(19) United States
(12) Patent Application Publication
(10) Pub. No.: US 2024/0413803 A1
(43) Pub. Date: Dec. 12, 2024

(54) ACOUSTIC RESONATOR SOLIDLY MOUNTED ON A HIGH ACOUSTIC VELOCITY SUBSTRATE

(71) Applicant: Huawei technologies Co., Ltd., Shenzhen (CN)

(72) Inventor: Viktor Plesski, Helsinki (FI)

(21) Appl. No.: 18/813,711

(22) Filed: Aug. 23, 2024

Related U.S. Application Data
(63) Continuation of application No. PCT/EP2022/055782, filed on Mar. 8, 2022.

(51) Int. Cl. H03H 9/02; H03H 9/13

(52) U.S. Cl. CPC H03H 9/0211; H03H 9/02031; H03H 9/02157; H03H 9/02228; H03H 9/132

(57) ABSTRACT

An acoustic resonator device comprises a substrate, a non-piezoelectric substrate layer on the substrate, a dielectric layer on the substrate layer, a piezoelectric plate, and two set of electrodes connected to a first busbar and second busbar, respectively, and arranged alternatingly with a pitch p on the piezoelectric plate.

### CROSS-REFERENCE TO RELATED APPLICATIONS

This application is a continuation of International Application No. PCT/EP2022/055782, filed on Mar. 8, 2022, the disclosure of which is hereby incorporated by reference in its entirety.

### TECHNICAL FIELD

The present disclosure relates to an acoustic resonator device. In particular, the disclosure provides a robust acoustic resonator device with an acoustic resonator comprising a piezoelectric plate, which is mounted solidly on a substrate (layer). The disclosure also provides a method for operating such an acoustic resonator device. The acoustic resonator device can be used in frequency passband filters, typically comprising a “ladder”-network of such resonator devices.

### BACKGROUND

Conventional acoustic resonator devices, which exploit a thin piezoelectric layer of sub-micron thickness as resonator material-which is often made of lithium niobate—for example, a bulk acoustic resonator (BAR) like a FBAR, XBAR or YBAR, have known drawbacks.

For example, a thin-film BAR (FBAR) is a bulk wave resonator. If such a bulk wave resonator is placed on a solid substrate with complete mechanic contact, it will not work efficiently, because acoustic energy will be radiated into the substrate. Therefore, no resonance (or only a resonance with a very low Q-factor) can be obtained in the piezoelectric layer.

To prevent this, the piezoelectric layer may be a thin membrane (plate) suspended over a cavity, wherein the cavity provides acoustic isolation. However, technologically such a device is difficult. Further, this approach leads to a very fragile device, since the piezoelectric membrane is very thin and not well supported (supported only at its edges). Further, the device has poor power-handling properties, because of a low thermal conductivity of the thin membrane and the heat evacuation mainly along thin and long electrodes.

Alternatively, the piezoelectric layer may be solidly attached to a Bragg stack, which is a system of many λ/4 layers alternating high and low acoustic impedances, and provides acoustic isolation. The multilayer Bragg stack serves, in particular, as a strong reflector at operation frequencies, and thus not allow the bulk waves to be radiated into the substrate. However, such Bragg stacks have their own disadvantages. For instance, a Bragg stack can lead to unwanted parasitic couplings between neighboring resonators, if metal layers are used. The presence of acoustic energy in the Bragg stack reduces the resonance-anti-resonance frequency distance, and thus reduces the passband of a filter, in which such resonator devices can be used. Further, a Bragg stack adds to the complexity of the fabrication process of the device.

### SUMMARY

In view of the above, this disclosure has the goal to provide an improved acoustic resonator device. An objective is to provide the acoustic resonator device with a piezoelectric layer on a solid substrate. The device should be suitable for operation at 5 GHz frequency range. The acoustic resonator device should avoid acoustic energy loss to the substrate, but should not require a reflecting structure like a Bragg stack. The acoustic resonator device should moreover be manufacturable with a critical dimension (CD) of electrodes being CD>0.3 μm.

These and other objectives are achieved by the solutions of this disclosure as described in the enclosed independent claims. Advantageous implementations are further defined in the dependent claims.

A first aspect of this disclosure provides an acoustic resonator device, comprising: a supporting substrate; a non-piezoelectric substrate layer arranged on the supporting substrate; a dielectric layer arranged on the substrate layer; a piezoelectric plate of thickness dix and having a front surface and a back surface, the back surface being covered by a metal layer and the piezoelectric plate being attached by the metal layer to the dielectric layer; and an interdigital electrode structure (IDES) including a first set of electrodes connected to a first busbar and a second set of electrodes connected to a second busbar, wherein the electrodes of the first and the second set are arranged alternatingly and periodically one after the other with a pitch p on the front surface of the piezoelectric plate; wherein a velocity V_{diam} of a slow-shear-bulk-wave propagating parallel to a layer surface in the substrate layer in direction perpendicular to said electrodes is higher than a phase velocity in the piezoelectric plate determined by Vₚₕ=2p*F_{R}, wherein F_{R} is an operation frequency of the acoustic resonator device determined by V_{LN}/(2d_{LN}); and wherein the pitch p satisfies the condition p<V_{diam}/V_{LN}*d_{LN}, wherein V_{LN} is the velocity of a bulk wave resonating in said piezoelectric plate.

The supporting substrate may be a thick substrate or wafer made of silicon, glass or other dielectric material. The substrate layer may have a high acoustic velocity, particularly, higher than the acoustic velocity of the piezoelectric plate. The bulk wave, when resonating in the piezoelectric plate, may be reflected between the sides of said piezoelectric plate. The electrodes of the first set may be of a different polarity than the electrodes of the second set, which means that in operation of the acoustic resonator device, voltages of different polarity will be applied to these electrodes. Thus, these first and the second set of electrodes could be referred to as “positive” electrodes and “negative” electrodes.

In the acoustic resonator device of the first aspect, on the one hand the pitch p between the electrodes of the first and the second set is sufficiently small, and on the other hand the substrate layer (e.g., made of diamond) has a sufficiently high velocity of acoustic waves, so that acoustic loss to the substrate is suppressed. For example, SH₁, S₁ (and even A₁) Lamb modes will not radiate acoustic energy into bulk of the substrate layer and the supporting substrate. The bulk waves or vibrations excited by the electrodes will only bounce up and down in the piezoelectric plate, but acoustic waves are not radiated into the substrate layer and below, at least they exponentially decay in the depth of the substrate.

For this reason, the acoustic resonator device of the first aspect is suitable for operation at 5 GHz frequency range, and is more stable than a conventional device with a piezoelectric membrane suspended over a cavity. Further, the device of the first aspect avoids the drawbacks of the acoustic energy loss to the substrate, without requiring a reflecting structure like a Bragg stack. The pitch is small but still well manufacturable with a CD>0.3 μm with currently existing technology.

In an implementation form of the first aspect, the substrate layer comprises a diamond layer, or a silicon carbide layer, or a boron nitride layer.

These materials have a sufficiently high acoustic velocity, specifically, a high velocity of the slow-shear-bulk-wave propagating parallel to the layer surface perpendicular to the electrodes. Thus, these kinds of materials are most suitable for the acoustic resonator device of this disclosure, and deliver the best results in terms of performance and low acoustic loss.

In an implementation form of the first aspect, the dielectric layer comprises at least one of a silicon dioxide layer, a SiOx layer, a SiNO layer, and a SiN layer.

Such a dielectric layer reduces acoustic coupling of the piezoelectric plate to the substrate layer. Further, it may decreases the influence of the substrate layer (e.g., vibration transferred from the piezoelectric plate to the substrate layer). It may allow also a fundamental thickness resonance in the piezoelectric plate, and increases the piezo-coupling.

In an implementation form of the first aspect, the piezoelectric plate is made of crystalline lithium niobate, or lithium tantalate, or aluminum nitride.

These materials provide best results (e.g., Q-factor, piezoelectric coupling estimated here by relative resonance anti-resonance frequency distance) for the acoustic resonator device of this disclosure. However, other piezoelectric materials may be suitable as well.

In an implementation form of the first aspect, the piezoelectric plate made of lithium niobate is a rotated YX-cut LN plate with the electrodes being arranged perpendicular to crystalline X-axis.

In an implementation form of the first aspect, the metal layer comprises a copper layer or an aluminum layer.

In an implementation form of the first aspect, the metal layer covers a limited area of the back surface of the piezoelectric plate, wherein the limited area corresponds to an area covered by the electrodes on the front surface of the piezoelectric plate and is at a floating potential.

Thus, a defined resonator region is defined between the metal layer and the electrodes of the IDES.

In an implementation form of the first aspect, the metal layer and the electrodes of the first and the second set form a plurality of periodically arranged resonators configured to oscillate with opposite phase.

This results in only little or no acoustic energy being leaked into the substrate.

In an implementation form of the first aspect, at least a first electrode and at least a last electrode, of the alternatingly arranged electrodes, are floating potential electrodes.

In an implementation form of the first aspect, the first electrode and the last electrode are configured to serve as reflectors for reducing radiation of acoustic energy outside the acoustic resonator device.

In an implementation form of the first aspect, a subset of the electrodes at a beginning and at an end of the IDES structure are at a floating potential.

The floating electrodes and/or reflector electrodes improve further the performance of the device of the first aspect, since acoustic energy loss is avoided also to the sides (higher Q-factor).

In an implementation form of the first aspect, a thickness of the substrate layer is in a range of 4-20 times the thickness dix of the piezoelectric plate.

In an implementation form of the first aspect, a thickness of the dielectric layer is about half the thickness d_{LN} of the piezoelectric plate and/or is about a quarter of a shear-wavelength in the dielectric layer.

For example, the thickness dix may be in a range of 0.25 μm-0.8 μm, wherein the pitch p may be in a range of 0.6 μm-1.2 μm.

In an implementation form of the first aspect, the velocity V_{diam} of the slow-shear-bulk-wave is larger than 8000 m/s, or is larger than 10000 m/s, or is larger than 12000 m/s.

In an implementation form of the first aspect, the phase velocity determined by Vₚₕ=2p*F_{R}, is in a range of 2000 m/s-6000 m/s and/or is lower than the velocity V_{diam} of the slow-shear-bulk-wave.

The above-given parameters of the acoustic resonator device lead to the best results (device performance, acoustic loss, etc.).

In an implementation form of the first aspect, a groove is arranged between each two adjacent electrodes of the electrodes of the first and the second set, wherein the groove extends into the piezoelectric plate or extends completely through the piezoelectric plate.

The grooves enable the electrodes to vibrate more freely increasing the piezo-coupling. Further, the presence of grooves may reduce propagation of parasitic waves.

A second aspect of this disclosure provides an acoustic resonator device, comprising: a diamond layer; a silicon dioxide layer arranged on the diamond layer; a lithium niobate plate with a front surface and a back surface, the back surface being covered by a metal layer and the lithium niobate plate being attached by this metal layer to the silicon dioxide layer; and an IDES including a first set of electrodes connected to a first busbar and a second set of electrodes connected to a second busbar, wherein the electrodes of the first and the second set are arranged alternatingly and periodically one after the other with a pitch p on the front surface of the piezoelectric plate, wherein a thickness dix of the lithium niobate plate is in a range of 0.25 μm-0.8 μm; and wherein the pitch p is in a range of 0.6 μm-1.2 μm.

The acoustic resonator device of the second aspect may have implementation forms that correspond to those of the acoustic resonator device of the first aspect. The acoustic resonator device of the second aspect achieves the same advantages and effects as the device of the first aspect. In particular, the acoustic resonator device of the second aspect is a particularly performant device.

A third aspect of this disclosure provides a method of operating an acoustic resonator device according to the first aspect or second aspect or any of their implementation forms. The method comprises: applying a differential AC voltage at the resonance frequency essentially close to V_{LN}/(2d_{LN}) between the first and the second busbar, to which the electrodes of the first and the second set are connected, respectively wherein the metal layer is grounded. Alternatively, the method comprises: applying an AC voltage at the resonance frequency essentially determined by V_{LN}/(2d_{LN}) to one of the first and the second busbar, and keeping the other one of the first and the second busbar at ground potential, wherein the metal layer is at a floating potential.

As described above, the aspects and implementation forms of this disclosure may comprise a periodic structure of relatively narrow FBARs (e.g., with SH₁ or S₁ Lamb modes/waves, or also with an A₁ Lamb mode), which periodic structure is solidly mounted on a high velocity substrate with resonances of opposite phase separated by the pitch p. The pitch p may satisfy the non-radiation condition p<λ/2, wherein λ is the (smallest) wavelength of any acoustic wave capable to propagate in the substrate at operation frequency.

In summary, the advantages of the solutions of this disclosure include the following. A particularly robust acoustic resonator device is provided, since it has a piezoelectric plate that is solidly mounted on the substrate and substrate layer, instead of having a fragile suspended membrane structure (notably, not directly on the substrate layer, as the dielectric layer is in between). Usual surface acoustic wave (SAW) technology may be used to manufacture the device, wherein the device may be manufactured using optical lithography. The device may be suitable for the 5 GHz frequency range. Strong piezo-coupling may further be achieved, for instance, a coupling of K²=20-25%. In addition, a high thermal conductivity of the substrate layer and the substrate may enable excellent power handling capabilities of the device. Further, the device may show only a low level of parasitic modes because of the small pitch (for comparison, XBARs may have an about 20 times larger pitch). The device also offers the possibility to change or tune the resonance frequency, for example, by changing the pitch and/or the electrode geometry.

Additionally in all described implementations, the acoustic resonator device can be covered on top by a thin (e.g., 15 nm-25 nm) protection (or “passivation”) dielectric layer of SiO₂, SiOx, Si₃N₄ to prevent oxidation of the electrodes and to protect from the influence of moisture, atmosphere, etc.

### BRIEF DESCRIPTION OF THE DRAWINGS

The above described aspects and implementation forms will be explained in the following description of specific embodiments in relation to the enclosed drawings, in which:

FIG. 1 shows an acoustic resonator device according to this disclosure in a perspective view. The schematic drawing shows the main features of the acoustic resonator device, while the geometric proportions, the number of electrodes, and other details may be not correctly presented.

FIG. 2 shows one period of an acoustic resonator device according to this disclosure in a cross-sectional view.

FIG. 3 shows an acoustic resonator device according to this disclosure in a perspective view.

FIG. 4 shows FEM simulation results of an acoustic resonator device with vibration close to shear plate mode (SH₁) according to this disclosure.

FIG. 5 shows X-cut simulation results of an acoustic resonator device according to this disclosure.

FIG. 6 shows simulation results of an acoustic resonator device operating on A₁ Lamb mode according to this disclosure.

FIG. 7 shows a parametric analysis of variations of a pitch and a thickness of a covering dielectric “passivation” layer of an acoustic resonator device according to this disclosure.

FIG. 8 shows an impact of the thickness of the dielectric layer (SiO₂) for coupling and Q-factor.

FIG. 9 shows an admittance of a finite acoustic resonator device according to this disclosure with floating reflector electrodes.

FIG. 10 shows methods for operating an acoustic resonator device according to this disclosure.

### DETAILED DESCRIPTION OF ILLUSTRATIVE EMBODIMENTS

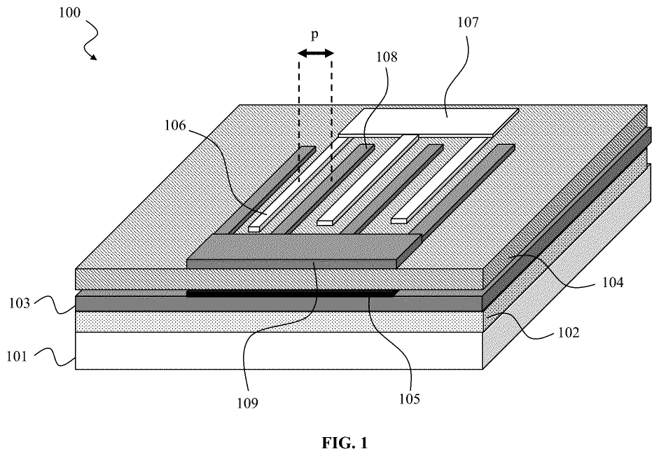

FIG. 1 shows an acoustic resonator device 100 according to this disclosure in a perspective view. The device 100 may be referred to as a bulk acoustic wave (BAW) or bulk acoustic resonator (BAR) device. In particular, the device 100 may be based on periodic system of narrow BAR pairs connected in series through a bottom electrode metal layer 105. The individual BARs with narrow width corresponding to the width of electrodes 106, 108 and interacting with their neighbors can be alternatively considered as a structure supporting standing SH₁ wave. The device 100 may further alternatively be considered as based on the SH₁ plate mode, or S₁ Lamb modes/waves (if compressional mode S₁ is excited with vertical displacements), or may also be based on the A₁ Lamb mode/wave. The choice of the operating mode is determined by the used cut of the piezoelectric plate 104 and many useful orientations suitable for excitation of SH₁, S₁, or A₁ mode are described in literature and known to a person skilled in the art. A common feature here is that the fundamental mode may be selected with the piezoelectric plate thickness close to one half of a corresponding acoustic wave bouncing between the piezoelectric plate sides.

The acoustic resonator device 100 shown in FIG. 1 comprises a supporting substrate 101, and a non-piezoelectric substrate layer 102 directly arranged on the supporting substrate 101. The supporting substrate 101 may be integral with the substrate layer 102, or may be made of the same material of the substrate layer 102. For example, the substrate layer 102 may comprise a diamond layer, or a silicon carbide layer, or a boron nitride layer. That is, the material of the substrate layer 102 and/or of the supporting substrate 101 may be diamond, silicon carbide, or boron nitride. The supporting substrate 101 may also be a silicon substrate or a dielectric substrate like glass. The acoustic impedances of these layers 101 and 102 may be selected in a way that only a minimal part of vibrational energy penetrates into the layer 102, and practically no vibration is found in the supporting substrate 101.

The device 100 further comprises a dielectric layer 103 directly arranged on the substrate layer 102. For instance, the dielectric layer 103 may be deposited or grown on top of the substrate layer 102. The dielectric layer 103 may comprise a silicon dioxide layer, a SiOx layer, a SiNO layer, and/or a SiN layer.

The device 100 further comprises the piezoelectric plate 104 arranged on the dielectric layer 103. The piezoelectric plate 104 has a certain thickness d_{LN} and has a front surface and a back surface (with respect to its direction defining the thickness, i.e., along the stacking direction of the layer stack shown in FIG. 1). The back surface may be covered by a metal layer 105, for instance, a copper or aluminum layer. The piezoelectric plate 104 is then attached by the metal layer 105 to the dielectric layer 103. That is, the metal layer 105 may be directly arranged on the dielectric layer 103, and the piezoelectric plate 104 directly on the metals layer 105. The piezoelectric plate 104 itself may be made of crystalline lithium niobate, or lithium tantalate, or aluminum nitride, for instance, it may be a rotated YX-cut lithium niobate plate.

The layers 103, 105 and the piezoelectric plate 104 create a waveguide structure, and practically all acoustic energy of the resonator is concentrated in these layers. The piezoelectric plate 104 with a strong piezo-effect is an important part of device 100, allowing excitation of acoustic vibrations and development of the resonance.

The device 100 further comprises interdigital electrode structure (IDES) which includes a first set of electrodes 106 and a second set of electrodes 108. The at least two electrodes 106, 108 may be made of metal, for example, of aluminum or copper. The first set of electrodes 106 are connected to a first busbar 107, and the second set of electrodes 108 are connected to a second busbar 109. The electrodes 106, 108 of the first set and of the second set are arranged alternatingly and periodically, one after the other, on the front surface of the piezoelectric plate 104 (which is opposite the back surface with respect to the thickness of the piezoelectric plate 104). The electrodes 106, 108 are periodically arranged with a certain pitch p . . . . In operation of the acoustic resonator device, an AC voltage may be applied to the corresponding busbars.

The acoustic resonator device 100 has the following characteristics. A velocity V_{diam} of a slow-shear-bulk-wave, which propagates parallel to a layer surface in the substrate layer 102 in a direction perpendicular to said electrodes 106, 108, is higher than a phase velocity in the piezoelectric plate 104. This phase velocity in the piezoelectric plate 104 is determined by Vₚₕ=2p*F_{R}. In this formula, F_{R} is an operation frequency of the acoustic resonator device 100, which is determined by V_{LN}/(2d_{LN}). Notably, the velocity V_{diam} is a material property of the material of the substrate layer 102. For example, diamond, silicon carbide, or boron nitride are materials with a comparatively high velocity V_{diam}.

Another characteristic of the acoustic resonator device 100 is that the pitch p satisfies the condition p<V_{diam}/V_{LN}*d_{LN}. In this formula, VIN is the velocity of a bulk wave resonating in the piezoelectric plate 104, which is a material property of the material of the piezoelectric plate 104. The velocity V_{diam} and the thickness dix are as explained above.

The characteristics of the acoustic resonator device 100 mentioned above, in particular, the velocities V_{diam}, V_{LN}, and Vₚₕ, are determined by the selection of the various materials for the individual layers/plates of the device 100. Examples of suitable materials are given above. In particular, the material of the substrate layer 103 and the piezoelectric plate 104 has the most impact on these parameters.

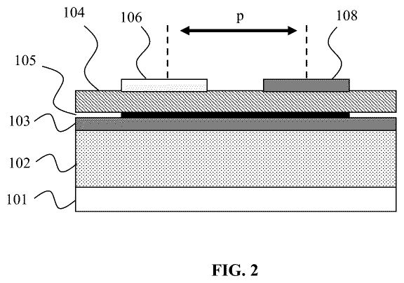

FIG. 2 shows an acoustic resonator device 100 according to this disclosure in a cross-sectional view. The acoustic resonator device 100 of FIG. 2 builds on, and may be the same as, the one shown in FIG. 1. Same elements in FIG. 2 and FIG. 1 are labelled with the same reference signs, and may be implemented like explained above with reference to FIG. 1.

The structure of the device 100 is multilayered and periodic. FIG. 2 illustrates a single period of the structure of the device 100, wherein this period may be multiplied for the device 100. For example, it is possible to have two, or more than two, or as many as hundreds of such periods in the device 100.

Each period comprises at least two electrodes 106, 108 of opposite polarities (e.g., at least one “positive” electrode 106 of the first set and at least one “negative” electrode 108 of the second set), which are arranged with the periodic pitch p. The pitch p is determined by the distance between centers of adjacent electrodes 106, 108 as illustrated. The pitch p may be approximately p<2.4 d_{LN}, for a lithium niobate plate 104 and diamond layer 102 wherein dix is the thickness of the piezoelectric plate 104.

As already shown in FIG. 1, the acoustic resonator device 100 comprises the piezoelectric plate 104, and the dielectric and non-piezoelectric layer 103 (e.g., a SiO₂ layer). The thickness of the piezoelectric plate 104 corresponds approximately to a half of wavelength of resonating wave d_{LN}=λ_{LN}/2, which determines the resonant frequencies: F_{R}=V_{LN}/(2d_{LN}). A thickness of the dielectric layer 103 may be about half the thickness dix of the piezoelectric plate 104, supposing that the wave velocities in both are comparable, like it has place in case of LN and SiO₂. For example, the thickness of the dielectric layer 103 may be about a quarter of a shear-wavelength in the dielectric layer 103. For the case of a SiO₂ layer 103, the thickness may thus be approximately λ_{SiO}_{₂}/4.

The dielectric layer 103 is placed between the piezoelectric plate 104 and the substrate layer 102 (e.g., a diamond layer). The dielectric layer 103 reduces acoustic coupling of the piezoelectric plate 104 to the substrate layer 102. Further, the dielectric layer 103 decreases the influence of the substrate layer 102 (e.g., in the case of a hard diamond material, i.e., vibration transferred from the piezoelectric plate 104 to the substrate layer 102 are strongly reduced and thus the influence of the layer 102 is also reduced. For example the acoustic attenuation in this layer 102 gives not much deterioration to Q-factor of the resonator device 100. Further, the dielectric layer 103 allows a fundamental thickness resonance in the piezoelectric plate 104, and, finally, increases the piezo-coupling.

The substrate layer 102 may be mounted or deposited on the supporting substrate 101, e.g., it may be provided by standard support wafer, made exemplarily from silicon or glass. But it may beneficially be dielectric, a conductive support substrate is not ideal to use. The substrate layer 102 can be a relatively thin layer (for example, only 4-20 times thicker than the piezoelectric plate 104). However, the substrate layer 102 may be sufficiently thick in relation to the piezoelectric plate 104, such that bulk waves may cancel each other due to destructive interference of waves with opposite phase generated under individual electrodes of the IDES. The thickness of the substrate layer 103 may be, for example, at least four times the thickness dix of the piezoelectric plate 104.

In the case of diamond used as material for the substrate layer 102, the diamond does not need to be perfect, i.e., it may contain crystalline grains of the size larger than 1 nm, in order to still benefit from its thermal conductivity and huge acoustic velocity (which may be about 12000 m/s). This is, because only a minor part of the acoustic energy is concentrated in the diamond. The substrate layer 102 may also be made of other materials, which are mechanically close to diamond and have a high velocity of (all) bulk acoustic waves. Such materials may be, for example, silicon carbide or boron nitride. The acoustic velocity of the substrate layer 102 may be, for example, twice as high as the acoustic velocity of the piezoelectric plate 104.

The pitch p fulfills the condition p<V_{diam}/V_{LN}*d_{LN}. The velocity V_{diam} may be larger than 8000 m/s, or may be larger than 10000 m/s, or may even be larger than 12000 m/s. The velocity V_{LN} may be around 4000 m/s in the piezoelectric plate 104. Thus—for example in the case of diamond as material for the substrate layer 102—the pitch p may be around 2.4 times smaller than the thickness of the piezoelectric plate 104. This allows to go to 5 GHz with a pitch p<1.2 μm, which is suitable for manufacturing with optical lithography.

The grooves can be created in piezoelectric plate 104 between the electrodes 106, 108 (partly or completely formed, e.g. etched, through the piezoelectric plate 104). The grooves enable the electrodes 106, 108 to vibrate more freely, thus increasing the piezo-coupling. Also, the presence of the grooves may reduce propagation of parasitic waves. The positive effect of grooves was proven experimentally for YBAR devices.

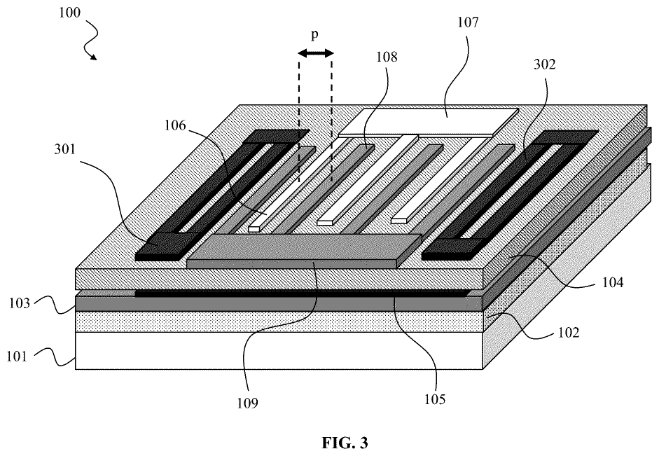

FIG. 3 shows an acoustic resonator device 100 according to this disclosure in a perspective view, wherein the acoustic resonator device 100 of FIG. 3 builds on, and may be the same as, shown in FIG. 1 and/or in FIG. 2. Same elements in FIG. 3 and FIG. 1 are labelled with the same reference signs, and may be implemented like explained above with reference to FIG. 1.

FIG. 3 illustrates that the device 100 may also comprise at least two reflector electrodes 301 and 302 arranged at the respective ends of the IDT structure. For example, at least the first electrode 301 and the last electrode 302 of all the electrodes arranged periodically on the piezoelectric plate 104 may be configured to serve as reflectors, in order to reduce radiation of acoustic energy outside the IDES created by the electrodes 106, 108 of the first set and the second set. The reflector electrodes 301, 302 may be floating electrodes, i.e., they may be at a floating potential, wherein these electrodes 301, 302 are not connected to any source of signal and not grounded.

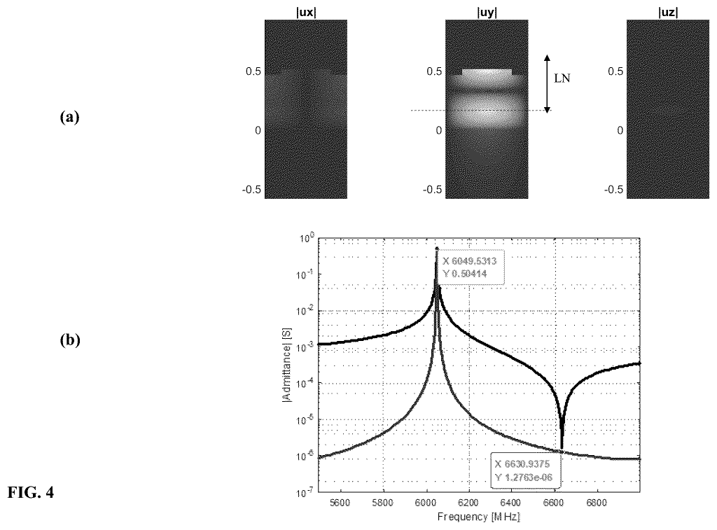

FIG. 4 illustrates simulation results of a periodic structure of an example acoustic resonator device 100 according to this disclosure. In this example, the piezoelectric plate 104 is made of lithium niobate (particularly, of a Y-cut lithium niobate with a 90° sidewall angle of Cu electrodes), the dielectric layer 103 is made of silicon dioxide (SiO₂), and the substrate layer 102 is made of diamond. The metal layer 105 and the electrodes 106, 108 are respectively made of copper. The pitch p is 0.7 μm (and 20 periods are used). The thickness of the piezoelectric plate 104 is 300 nm, the thickness of the electrodes 106, 108 is 50 nm, the thickness of the metal layer 105 is 10 nm, and the thickness of the dielectric layer 103 is 150 nm.

The resonance frequency is 6049.3 MHz, the resonance Q-factor is 4130, the anti-resonance frequency is 6632.6 MHz, the anti-resonance Q-factor is 3620, and the relative resonance-anti-resonance frequency is 9.20%. The admittance is calculated for one pair of electrodes with aperture W=20*(2p). In 2D FEM simulation resistive loss in the electrodes 106, 108, and many other loss mechanisms were ignored. Indicated Q-factors can be considered as an ideal limit not achievable in practical device, where expected Q-factors will be in the range 300-600.

In FIG. 4(a), the amplitude inside the resonator is shown in grey scale (dark grey being “zero”), wherein at o of vertical axis is the interface position between the diamond substrate layer 102 and the SiO₂ dielectric layer 103. Practically no waves are radiated to the diamond substrate layer 102 and substrate (below the interface marked as “0”), but they bounce up and down in the piezoelectric plate 104. It is seen that basically only shear SH₁ component uy of displacements is present in simulated Y-cut LN piezoelectric plate (electrodes being perpendicular to crystalline X-axis)

The curve in FIG. 4(b) shows the admittance per one pair of electrodes 106, 108 (one period including an electrode 106 of the first set and an electrode 108 of the second set, as illustrated in FIG. 2). A Y-cut lithium niobate is used as piezoelectric plate 104. However, other possible cuts exist, and may comprise, for example, Z, Y+64, Y+36 degree cut for S₁ mode propagation, and Y+163 degree cut for SH₁ mode.

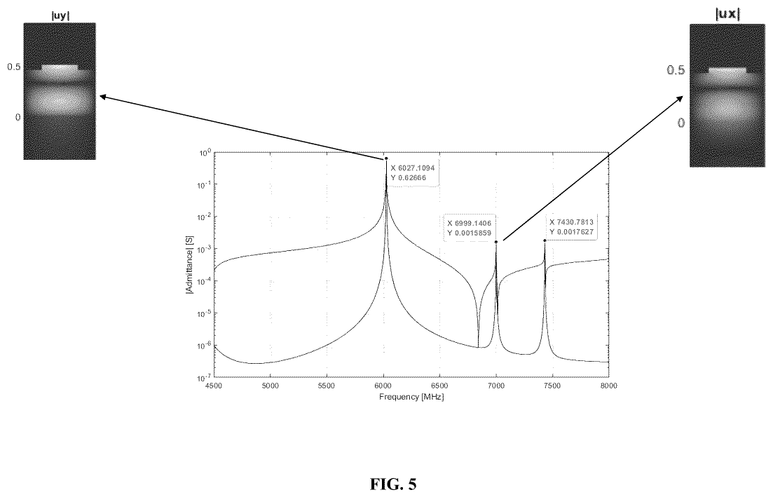

The proposed cuts may provide even stronger coupling. As an additional example, FIG. 5 shows similar results for another cut of lithium niobate (X-cut, 30° propagation) used for an acoustic resonator device 100 according to this disclosure. Even higher coupling can be obtained with R-a-R relative frequency gap of 12.7%, (K^{2>25}%). However, the parasitic mode appears near 7000 MHz, with horizontal displacements. The position and strength of this mode depends on the device geometry which may be further optimized.

The same approach works for the S₁ mode (classic FBAR with longitudinal waves propagating in z-direction). For the S₁ mode, the coupling may be weaker than for the SH₁ mode in case of a piezoelectric plate 104 made of lithium niobate and/or lithium tantalate.

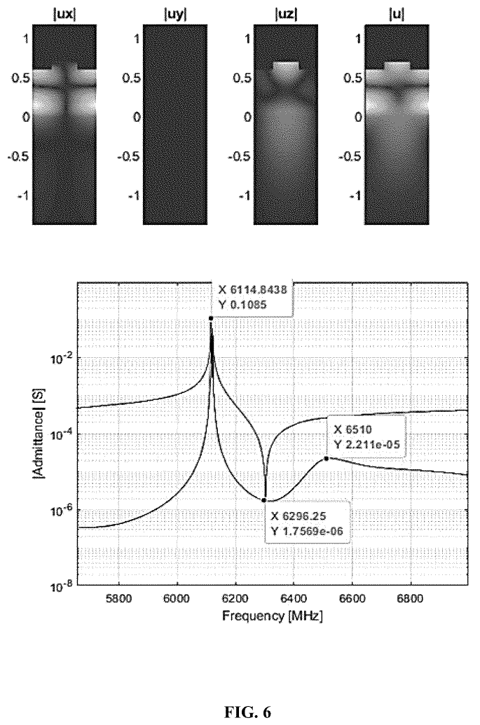

The approach may be used also for A₁ mode, as shown in FIG. 6. In this case no metal layer 105 between the piezoelectric plate 104 and the dielectric layer 103 is needed. The electrodes 106, 108 may be narrower with a larger spacing between them (the metallization ratio may be a/p<0.5). The main displacement component is ux (horizontal in FIG. 6), and there is no y-vibration uy. This corresponds to a “solidly mounted XBAR”.

FIG. 6 shows, in particular, simulation results of a device with the A₁ lamb mode on diamond. The coupling K² is about 5% in this case (compared to the typical 20% for SH₁ mode). The field distribution is typical for XBARs, and the waves decay fast in the depth of the diamond substrate layer 102. Hence, there is no bulk wave radiation.

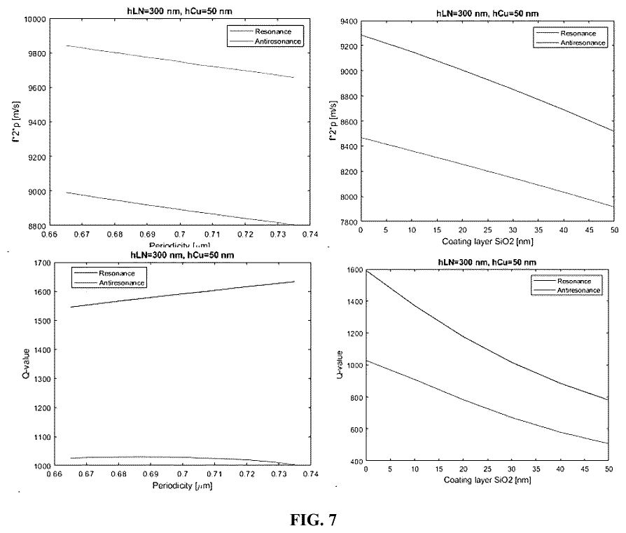

FIG. 7 illustrates a parametric analysis of the solution of this disclosure for the main SH₁ case. The left column shows that the resonance frequency (top left) and the Q-factor (bottom left) slightly depend on the pitch p. The piezoelectric plate 104 (here lithium niobate as example) defines the resonance frequency, wherein f=V_{LN}/(2d_{LN}) and VIN is the velocity of sound in the piezoelectric plate 104. The frequency may be tuned by changing the pitch p or by changing the geometry of the electrodes 106, 108, for example, by changing the width of the electrodes 106, 108, or by constructing the electrodes 106, 108 with a trapezoidal cross-section shape.

In practice the whole device is often covered by the “passivation layer”, such as thin layer of SiOx, silicon nitride, etc. to protect the electrodes 106, 108 from oxidation, moisture, etc. The right column in FIG. 7 shows how such a top cover dielectric layer not shown in FIG. 1-3 (here as an example SiO₂) may be used for small variation of the resonance and anti-resonance frequency. With the thickness of the “passivation” dielectric layer covering whole resonator device, the Q-factor, and the resonance/anti-resonance frequency gap (coupling) is decreased.

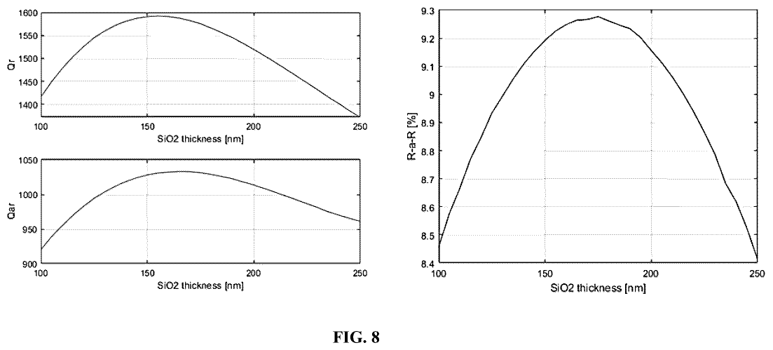

FIG. 8 illustrates the impact of the thickness of the dielectric layer 103. For the device geometry illustrated in FIG. 2, the optimal thickness of the dielectric layer (e.g., made of SiO₂) is around 180 nm (e.g. around λ_{SiO}_{₂}/4) at a given frequency. However, a maximum piezo-coupling K² may not be always needed, and the thickness of the dielectric layer 103 may also be, for example, within a range of 150-200 nm, or around +/−10% from the optimum value.

The temperature coefficient of frequency (TCF) characterizes the thermal frequency stability of resonators. The TCF can be improved for the device 100 of this disclosure, due to the presence of the dielectric layer 103 with positive temperature coefficient of frequency (TCF) contrary to negative TCF for LN, which adds to the temperature stability of the structure, and due to the low expansion coefficient of the substrate layer 102 (e.g., diamond or SiC).

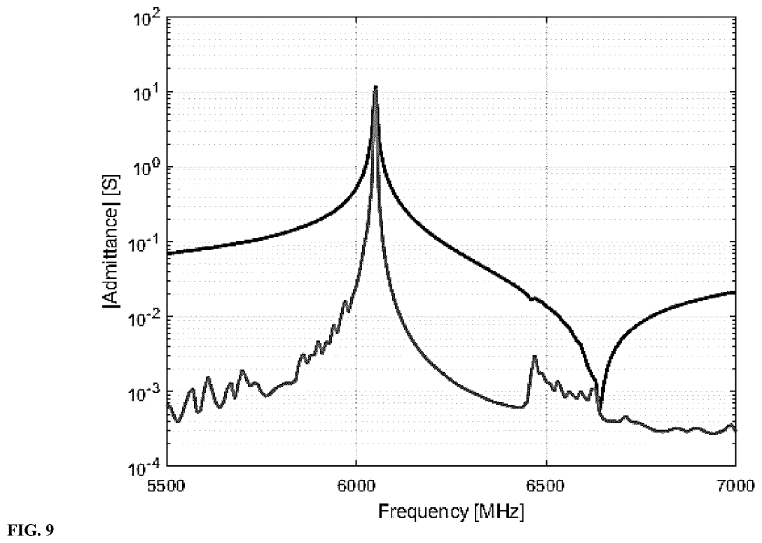

FIG. 9 shows FEM simulation results of a finite acoustic resonator device 100 according to this disclosure with 121 periods of the proposed periodic structure and the floating reflectors 301, 302 shown in FIG. 3, respectively. Improved results may be provided with the floating reflectors 301, 302. The results of the device 100 in FIG. 9 confirm that the simulation of a periodic device structure (when only one period is simulated) also works for a device having multiple periods of the same structure.

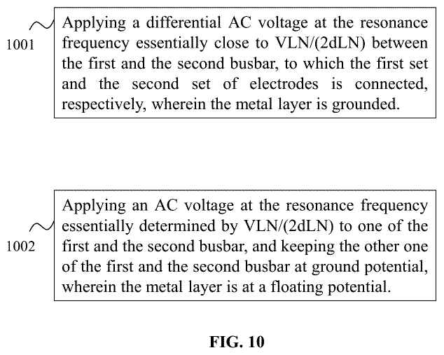

FIG. 10 shows possible methods 1001 and 1002 of operating an acoustic resonator device 100 according to this disclosure. For instance, one of the acoustic resonator devices 100 shown in FIG. 1, FIG. 2 or FIG. 3.

The method 1001 comprises applying a differential AC voltage at the resonance frequency essentially close to V_{LN}/(2d_{LN}) between the first and the second busbar 107, 109, to which the electrodes 106, 108 of the first set and the second set are connected, respectively, wherein the metal layer 105 is grounded. This method 1001 can be used in the lattice type of filters with balanced input/output. These filters are relatively rarely used now because of complicated network in duplexers and multiplexers is demanded.

Alternatively, the method 1002 comprises applying an AC voltage at the resonance frequency essentially determined by V_{LN}/(2d_{LN}) to one of the first and the second busbar 107, 109, and keeping the other one of the first and the second busbar 107, 109 at ground potential (or another potential), wherein the metal layer 105 is at a floating potential. This is the method of using this resonator device in the “ladder” type filters with single-ended signals.

The present disclosure has been described in conjunction with various embodiments as examples as well as implementations. However, other variations can be understood and effected by those persons skilled in the art and practicing the claimed matter, from the studies of the drawings, this disclosure and the independent claims. In the claims as well as in the description the word “comprising” does not exclude other elements or steps and the indefinite article “a” or “an” does not exclude a plurality. A single element or other unit may fulfill the functions of several entities or items recited in the claims. The mere fact that certain measures are recited in the mutual different dependent claims does not indicate that a combination of these measures cannot be used in an advantageous implementation.

What is claimed is:

1. An acoustic resonator device, comprising:
a substrate;
a non-piezoelectric substrate layer on the substrate;
a dielectric layer on the non-piezoelectric substrate layer;
a piezoelectric plate of thickness dix and having a front surface and a back surface, the back surface being covered at least in part by a metal layer, and the piezoelectric plate being attached by the metal layer to the dielectric layer; and
an interdigital electrode structure (IDES) comprising a first set of electrodes connected to a first busbar and a second set of electrodes connected to a second busbar, wherein electrodes of the first set of electrodes and the second set of electrodes are arranged alternatingly and periodically one after the other with a pitch p on the front surface of the piezoelectric plate;
wherein a velocity V_{diam} of a slow-shear-bulk-wave propagating parallel to a layer surface in the non-piezoelectric substrate layer that is in a direction that is perpendicular to an arrangement direction of the first set electrodes and the second set of electrodes is higher than a phase velocity in the piezoelectric plate determined by Vₚₕ=2p*F_{R}, wherein F_{R} is an operation frequency of the acoustic resonator device determined by V_{LN}/(2d_{LN}); and
wherein the pitch p satisfies the condition p<V_{diam}/V_{LN}*d_{LN}, wherein VIN is the velocity of a bulk wave resonating in the piezoelectric plate.

2. The acoustic resonator device according to claim 1, wherein the non-piezoelectric substrate layer comprises a diamond layer, or a silicon carbide layer, or a boron nitride layer.

3. The acoustic resonator device according to claim 1, wherein:
the dielectric layer comprises at least one of a silicon dioxide layer, a SiOx layer, a SiNO layer, or a SiN layer.

4. The acoustic resonator device according to claim 1, wherein:
the piezoelectric plate is made of crystalline lithium niobate, or lithium tantalate, or aluminum nitride.

5. The acoustic resonator device according to claim 4, wherein:
the piezoelectric plate made of lithium niobate is a rotated YX-cut lithium niobate plate with the electrodes of the first set of electrodes and the second set of electrodes being arranged perpendicular to a crystalline X-axis.

6. The acoustic resonator device according to claim 1, wherein:
the metal layer comprises a copper layer or an aluminum layer.

7. The acoustic resonator device according to claim 6, wherein:
the metal layer covers a limited area of the back surface of the piezoelectric plate, wherein the limited area corresponds to an area covered by the electrodes of the first set of electrodes and the second set of electrodes on the front surface of the piezoelectric plate and is at a floating potential.

8. The acoustic resonator device according to claim 1, wherein:
the metal layer and the electrodes of the first set of electrodes and the second set of electrodes form a plurality of periodically arranged resonators configured to oscillate with opposite phase.

9. The acoustic resonator device according to claim 1, wherein:
at least a first electrode and at least a last electrode, of the alternatingly arranged electrodes, are floating potential electrodes.

10. The acoustic resonator device according to claim 9, wherein:
the first electrode and the last electrode are configured to serve as reflectors for reducing radiation of acoustic energy outside the acoustic resonator device.

11. The acoustic resonator device according to claim 1, wherein:
a subset of the electrodes of the first set of electrodes and the second set of electrodes that are at a beginning and at an end of the IDES structure are at a floating potential.

12. The acoustic resonator device according to claim 1, wherein:
a thickness of the non-piezoelectric substrate layer is in a range of 4-20 times the thickness din of the piezoelectric plate.

13. The acoustic resonator device according to claim 1, wherein:
a thickness of the dielectric layer is a half the thickness din of the piezoelectric plate or is a quarter of a shear-wavelength in the dielectric layer.

14. The acoustic resonator device according to claim 1, wherein:
the velocity V_{diam} of the slow-shear-bulk-wave is larger than 8000 m/s.

15. The acoustic resonator device according to claim 1, wherein:
the phase velocity determined by Vₚₕ=2p*F_{R}, is in a range of 2000 m/s-6000 m/s, or is lower than the velocity V_{diam} of the slow-shear-bulk-wave.

16. The acoustic resonator device according to claim 1, wherein:
a groove is between each two adjacent electrodes of the electrodes of the first set of electrodes and the second set of electrodes, wherein each groove extends into the piezoelectric plate or extends completely through the piezoelectric plate.

17. An acoustic resonator device, comprising:
a diamond layer;
a silicon dioxide layer on the diamond layer;
a lithium niobate plate with a front surface and a back surface, the back surface being covered at least in part by a metal layer, and the lithium niobate plate being attached by the metal layer to the silicon dioxide layer; and
an interdigital electrode structure (IDES) comprising a first set of electrodes connected to a first busbar and a second set of electrodes connected to a second busbar, wherein the electrodes of the first set of electrodes and the second set of electrodes are arranged alternatingly and periodically one after the other with a pitch p on the front surface of the lithium niobate plate;
wherein a thickness din of the lithium niobate plate is in a range of 0.25 μm-0.8 μm; and
wherein the pitch p is in a range of 0.6 μm-1.2 μm.

18. A method of operating an acoustic resonator device, the method comprising:
applying a differential AC voltage at a resonance frequency of V_{LN}/(2d_{LN}) between a first and a second busbar, wherein a metal layer is grounded; or
applying an AC voltage at the resonance frequency of by V_{LN}/(2d_{LN}) to one of the first and the second busbar, and keeping the other one of the first and the second busbar at ground potential, wherein the metal layer is at a floating potential;
wherein the acoustic resonator device comprises:
a substrate;
a non-piezoelectric substrate layer on the substrate;
a dielectric layer on the non-piezoelectric substrate layer;
a piezoelectric plate of thickness dix and having a front surface and a back surface, the back surface being covered at least in part by the metal layer, and the piezoelectric plate being attached by the metal layer to the dielectric layer; and
an interdigital electrode structure (IDES) comprising a first set of electrodes connected to the first busbar and a second set of electrodes connected to the second busbar, wherein electrodes of the first set of electrodes and the second set of electrodes are arranged alternatingly and periodically one after the other with a pitch p on the front surface of the piezoelectric plate;
wherein a velocity V_{diam} of a slow-shear-bulk-wave propagating parallel to a layer surface in the non-piezoelectric substrate layer that is in a direction that is perpendicular to an arrangement direction of the first set electrodes and the second set of electrodes is higher than a phase velocity in the piezoelectric plate determined by Vₚₕ=2p*F_{R}, wherein F_{R} is an operation frequency of the acoustic resonator device determined by V_{LN}/(2d_{LN}); and
wherein the pitch p satisfies the condition p<V_{diam}/V_{LN}*d_{LN}, wherein V_{LN} is the velocity of a bulk wave resonating in the piezoelectric plate.
